(19) United States
(12) Patent Application Publication
(10) Pub. No.: US 2014/0240928 A1
(43) Pub. Date: Aug. 28, 2014

(54) THERMAL GREASE HAVING LOW THERMAL RESISTANCE

(71) Applicant: 3M INNOOVATIVE PROPERTIES COMPANY, St. Paul, MN (US)

(72) Inventors: Pei Tien, Taoyuan (TW); Chia Hui Lin, Tainan City (TW); Chao-Yuan Wang, Taipei (TW); Ravi K. Sura, Woodbury, MN (US)

(21) Appl. No.: 14/348,959

(22) PCT Filed: Sep. 28, 2012
(86) PCT No.: PCT/US2012/057920

§ 371 Date: Apr. 1, 2014

Related U.S. Application Data
(60) Provisional application No. 61/544,801, filed on Oct. 7, 2011.

(51) Int. Cl. C10M 169/04; H05K 1/02

(52) U.S. Cl. CPC C10M 169/04; H05K 1/0204
USPC 361/709; 508/150; 508/172; 361/748

(57) ABSTRACT

A thermally conductive grease includes a carrier oil, at least one dispersant, and thermally conductive particles. The thermally conductive particles have a D50 (Vol. Average) particle size of no greater than about 11 microns and the thermally conductive particles in the thermally conductive grease contain less than 3% by volume of particles having a particle size of 0.7 microns or less, based on the total volume of thermally conductive particles in the thermally conductive grease.

### CROSS REFERENCE TO RELATED APPLICATIONS

This application claims priority from U.S. Provisional Application Ser. No. 61/544,801, filed Oct. 7, 2011, the disclosure of which is incorporated by reference in its/their entirety herein.

### TECHNICAL FIELD

The invention relates to thermal interface materials and their uses. In particular, this invention relates to thermal grease having low thermal resistance.

### BACKGROUND

In the computer industry, there is a continual movement to higher computing power and speed. Microprocessors are being made with smaller and smaller feature sizes to increase calculation speeds. Consequently, power flux is increased and more heat is generated per unit area of the microprocessor. As the heat output of the microprocessors increases, heat or “thermal management” becomes more of a challenge.

One aspect of thermal management is known in the industry as a “thermal interface material” or “TIM” whereby such a material is placed between a heat source, such as a microprocessor, and a heat dissipation device to facilitate the heat transfer. Such TIMs may be in the form of a grease or a sheet-like material. These thermal interface materials are also used to eliminate any insulating air between the microprocessor and heat dissipation device.

TIMs are typically used to thermally connect a heat source to a heat spreader, that is, a thermally conductive plate larger than the heat source, in which case they are referred to as TIM Is. TIMs may also be employed between a heat spreader and a thermal dissipation device such as a cooling device or a finned heat sink in which case such TIMs are referred to as TIM IIs. TIMs may be present in one or both locations in a particular installation.

### SUMMARY

In one embodiment, the present invention is a thermally conductive grease. The thermally conductive grease includes a carrier oil, at least one dispersant, and thermally conductive particles. The thermally conductive particles have a D50 (Vol. Average) particle size of no greater than about 11 microns and the thermally conductive particles in the thermally conductive grease contain less than 3% by volume of particles having a particle size of 0.7 microns or less, based on the total volume of thermally conductive particles in the thermally conductive grease.

In another embodiment, the present invention is a microelectronic package including a substrate, at least one microelectronic heat source attached to the substrate, and the thermally conductive grease on the microelectronic heat source.

In yet another embodiment, the present invention is a method of making a thermally conductive grease. The method includes providing a carrier oil, a dispersant, and thermally conductive particles; mixing the carrier oil and dispersant to form a mixture; and mixing the thermally conductive particles into the mixture. The thermally conductive particles have a D50 (Vol. Average) particle size of no greater than about 11 microns and the thermally conductive particles in the thermally conductive grease contain less than 3% by volume of particles having a particle size of 0.7 microns or less, based on the total volume of thermally conductive particles in the thermally conductive grease.

In yet another embodiment, the present invention is a thermally conductive grease including a carrier oil, a dispersant, and thermally conductive particles. The thermally conductive particles have a D50 (Vol. Average) particle size of no greater than about 7 microns and no less than about 0.9 microns.

### DETAILED DESCRIPTION

As used herein:

“Grease” means a material having a viscosity of greater than 1×10⁴ cps (10 Pa·s) at 1/s shear rate and 20° C. and a viscosity of less than 10⁸ cps at 1/sec shear rate and 125° C.

“Thermally conductive grease” means grease having a bulk conductivity of greater than 0.05 W/m-K.

All numbers are herein assumed to be modified by the term “about,” unless stated otherwise. The recitation of numerical ranges by endpoints includes all numbers subsumed within that range (e.g., 1 to 5 includes 1, 1.5, 2, 2.75, 3, 3.80, 4, and 5).

The thermally conductive greases (TCGs) of the present invention include a carrier oil, a dispersant, and thermally conductive particles. The TCGs of the present invention have low thermal resistance, good screen printing properties and good thermal conductivity values. In order for the TCG to have lower thermal resistance and good screen printing properties, the particle size of the thermally conductive particles must be balanced with the amount of carrier oil. If the particle size of the thermally conductive particles is too small, the increased surface area and interfaces may increase the thermal resistance of the TCG. Therefore, the amount of carrier oil in the TCG increases as the particle size of the thermally conductive particles decreases and increases as the particle size of the thermally conductive particles increases. However, the amount of carrier oil will also affect the thermal resistance of the TCG. Too much carrier oil will increase the thermal resistance of the TCG while not enough carrier oil will result in poor screen printing properties.

The carrier oil provides the base or matrix for the TCGs. Useful carrier oils may comprise synthetic oils or mineral oils, or a combination thereof and are typically flowable at ambient temperature. Suitable carrier oils include silicone oils and hydrocarbon based oils. Specific examples of useful hydrocarbon based carrier oils include polyol esters, epoxides, and polyolefins or a combination thereof.

Commercially available carrier oils include HATCOL 1106, a polyol ester of dipentaerythritol and short chain fatty acids, HATCOL 3371, a complexed polyol ester of trimethylol propane, adipic acid, caprylic acid, and capric acid and HATCOL 2938, a polyol ester lubricant based on trimethylolpropane (all available from Hatco Corporation, Fords, N.J.); HELOXY 71 an aliphatic epoxy ester resin, available from Hexion Specialty Chemicals, Inc., Houston, Tex.; and SILICONE OIL AP 100, a silicone oil, available from Sigma-Aldrich, St. Louis, Mo.

The carrier oil may be present in the TCGs in an amount of up to about 12 weight percent, particularly up to about 20 weight percent and more particularly up to about 49.5 weight percent of the total composition. In other embodiments, the carrier oil may be present in an amount of at least about 0.5 weight percent, particularly at least about 1 weight percent, and more particularly at least about 2 weight percent of the total composition. The carrier oil may also be present in the TCGs of the invention in a range of between about 0.5 to about 20 weight percent, particularly between about 1 to about 15 weight percent, and more particularly between about 2 to about 12 weight percent.

TCGs of the present invention can contain one or more dispersants. The dispersant(s) may be present in combination with the carrier oil, or may be present in the absence of carrier oil. The dispersants improve the dispersion of the thermally conductive particles (described below) in the carrier oil if present. Useful dispersants may be characterized as polymeric or ionic in nature. Ionic dispersants may be anionic or cationic. In some embodiments, the dispersant may be nonionic. Combinations of dispersants may be used, such as, the combination of an ionic and a polymeric dispersant. In some embodiments, a single dispersant is used.

Examples of useful dispersants include, but are not limited to: polyamines, sulfonates, modified polycaprolactones, organic phosphate esters, fatty acids, salts of fatty acids, polyethers, polyesters, and polyols, and inorganic dispersants such as surface-modified inorganic nanoparticles, or any combination thereof.

Examples of commercially available dispersants include those having the tradenames SOLSPERSE 24000, SOLSPERSE 16000 and SOLSPERSE 39000 hyperdispersants, available from Noveon, Inc., a subsidiary of Lubrizol Corporation, Cleveland, Ohio; EFKA 4046, a modified polyurethane dispersant, available from Efka Additives BV, Heerenveen, the Netherlands; MARVEL 1186, an oil based dispersant, available from Marvel Chemical Co. Ltd., Taipei Taiwan and RHODAFAC RE-610, an organic phosphate ester, available from Rhone-Poulenc, Plains Road, Granbury, N.J.

The dispersant is present in the TCGs in an amount of between about 0.5 and about 50 weight percent. In one embodiment, the dispersant is present up to about 5 weight percent, particularly up to about 10 weight percent and more particularly up to about 25 weight percent of the total composition. In another embodiment, the dispersant may be present in an amount of at least about 1 weight percent. The dispersant may also be present in the TCGs of the invention in a range of from between about 1 to about 5 weight percent.

The TCGs of the present invention contain thermally conductive particles. Generally any thermally conductive particles known to those of skill in the art can be used. Examples of suitable thermally conductive particles include, but are not limited to, those made from or that comprise diamond, polycrystalline diamond, silicon carbide, alumina, boron nitride (hexagonal or cubic), boron carbide, silica, graphite, amorphous carbon, aluminum nitride, aluminum, zinc oxide, nickel, tungsten, silver, carbon black and combinations of any of them. Although silica is listed as a thermally conductive particle, it is important to specify that fumed silica is not considered to be a useful, thermally conductive particle. Fumed silica is silica particles which have a primary particle size of less than about 200 nm that have been fused together into branched, three dimensional aggregates. The branched, three dimensional aggregates typically comprise chain-like structures.

In order for the TCG to have lower thermal resistance and good screen printing properties, the particle size of the thermally conductive particles must be controlled to a specific size range. If the particle size is too large, it is believed that the large particle size will lead to an increased thickness of the TIM, as the large particle size limits how thin the TIM can be made when it is placed between two components during use. This increased thickness is thought to increase the thermal resistance of the TIM. If the particle size or a fraction of the particle size in a given distribution of particles is too small, it may be difficult to fully wet and disperse the particles into the thermally conductive grease, resulting in poor flow properties and screen printability of the grease In some embodiments, the thermally conductive particles have a D50 (Vol. Average) particle size of no greater than about 11 microns, no greater than about 7 microns, no greater than about 5 microns and no greater than about 4 microns. In some embodiments, the thermally conductive particles have a D50 (Vol. Average) particle size of no less than 3 microns, no less than about 2 micron, no less than about 1 microns, no less than about 0.9 microns and no less than about 0.7 microns. In some embodiments, the range in the D50 (Vol. Average) particle size is from 0.7 to 11 microns, from 0.9 to 7 microns, from 2 to 5 microns and from 2 to 4 microns. In some embodiments, the thermally conductive particles in the thermally conductive grease contain less than 3% by volume, less than 2% by volume and even less than 1% by volume of particles having a particle size of 0.7 microns or less, based on the total volume of particles in the thermally conductive grease.

In one embodiment, the thermally conductive particles in the TCG contain less than about 3% by volume of particles having a particle size of 0.7 microns or less, based on the total volume of thermally conductive particles in the TCG. A majority of the thermally conductive particles have a particle size of at least about 0.7 microns. In some embodiments, at least about 80%, about 90%, about 95%, about 97%, about 98% or about 99% by volume of the thermally conductive particles have a particle size greater than 0.7 microns, based on the total volume of thermally conductive particles in the TCG.

In some embodiments, it is desirable to provide a TCG having the maximum possible volume fraction of thermally conductive particles that is consistent with the desirable physical properties of the resulting TCG, for example, that the TCG conform to the surfaces with which it is in contact and that the TCG be sufficiently flowable to allow easy application.

In one embodiment, the thermally conductive particles may be present in the TCGs of the invention in an amount of at least about 50 percent by weight. In other embodiments, the thermally conductive particles may be present in amounts of at least about 70, about 75, about 80, about 85, about 86, about 87, about 88, about 89, about 90, about 91, about 92, about 93, about 94, about 95, about 96, about 97, or about 98 weight percent. In other embodiments, the thermally conductive particles may be present in the TCGs of the invention in an amount of up to about 99, about 98, about 97, about 96, about 95, about 94, about 93, about 92, about 91, about 90, about 89, about 88, about 87, about 86, or about 85 weight percent.

The TCGs and TCG compositions of the present invention may also optionally include additives such as, but not limited to: antiloading agents, antioxidants, leveling agents and solvents (to reduce application viscosity), for example, methylethyl ketone (MEK), methylisobutyl ketone, and esters such as butyl acetate.

In one embodiment, the TCG includes a thixotropic agent, e.g. fumed silica, to prevent wet-out during screen printing. Examples of commercially available thixotropic agents include those having the tradenames CAB-O-SIL M5 and CAB-O-SIL TS-610, both available from Cabot Corporation, Boston, Mass.

In one embodiment, the thermal resistance of the TCGs of the present invention is less than about 0.15° C.×cm²/W, particularly less than about 0.13° C.×cm²/W, more particularly less than about 0.12° C.×cm²/W, more particularly less than about 0.11° C.×cm²/W and even more particularly less than about 0.10° C.×cm²/W.

The TCGs of the present invention are generally made by blending dispersant and carrier oil together, and then blending the thermally conductive particles sequentially, finest to largest average particle size into the dispersant/carrier oil mixture. The thermally conductive particles may also be premixed with one another, and then added to the liquid components. Heat may be added to the mixture in order to reduce the overall viscosity and aid in reaching a uniformly dispersed mixture. In some embodiments, it may be desirable to first pre-treat or pre-disperse a portion or all of the thermally conductive particles with dispersant prior to mixing the particles into the dispersant/carrier mixture.

In other embodiments, the TCGs can be made by solvent casting the blended components, then drying to remove the solvent. For example, the TCG component blend can be provided on a suitable release surface, e.g., a release liner or carrier.

In other embodiments, the TCGs can be applied to a carrier, or to the device in the intended use, with the aid of an energy source, e.g., heat, light, sound, or other known energy source.

In some embodiments, preferred combinations of materials of the present invention incorporate Hatcol 2938 as the carrier, Marvel 1186 as dispersant, and a blend of zinc oxide and spherical aluminum.

The TCGs of the present invention may be used in microelectronic packages and may be used to assist in the dissipation of heat from a heat source, for example, a microelectronic die or chip to a thermal dissipation device. Microelectronic packages may comprise at least one heat source, for example, a die mounted on a substrate or stacked die on a substrate, a thermally conductive grease of the invention on the heat source, and may include an additional thermal dissipation device in thermal and physical contact with the die, such as, for example, a thermal spreader. A thermal spreader may also be a heat source for any subsequent thermal dissipation device. The thermally conductive greases of the invention are useful to provide thermal contact between said die and thermal dissipation device. Additionally, TCGs of the present invention may also be used in thermal and physical contact between a thermal dissipation device and a cooling device. In another embodiment, the TCGs of the present invention may be used between a heat generating device and a cooling device, that is, without using a heat or thermal spreader in between. TCGs of the invention are useful in TIM I and TIM II applications.

### EXAMPLES

The present invention is more particularly described in the following examples that are intended as illustrations only, since numerous modifications and variations within the scope of the present invention will be apparent to those skilled in the art. Unless otherwise noted, all parts, percentages, and ratios reported in the following example are on a weight basis.

### Test Methods

### Thermal Resistance

The thermal resistance was measured according to ASTM 5470-06 using a model number LW9389 TIM Thermal Resistance and Conductivity testing apparatus available from Long Win Science and Technology Corporation, Yangmei, Taiwan. Reported values for thermal resistance were taken at a pressure of 80 psi.

### D50 and D100 Particle Size

The D50 (mass median diameter based on the log normal distribution) and D100 particle sizes were obtained from the suppliers of the thermally conductive powders. They were obtained using conventional light scattering techniques and equipment, such as a Hydro 2000 MU, available from Malvern Instruments, Ltd., Worcestershire, United Kingdom.

D50 (Vol. Average) Particle Size

For a thermal grease formulation having multiple particle types, the D50 (Vol. Average) particle size of the particles in the formulation was calculated based on a volume average of the individual D50s. Using the density of aluminum as 2.7 g/cm³, the density of silicon carbide as 3.21 g/cm³, the density of zinc oxide as 5.606 g/cm³ and the density of aluminum oxide of 4.02 g/cm³, the volume of each type of mineral in each formulation was calculated. The D50 (Vol. Average) particle size can then be calculated. A sample calculation follows. Suppose a formulation has 19.1 parts by volume (pbv) of a first particle having a D50 of 12.2, 8.0 pbv of a second particle having a D50 particle size of 1.5 and 2.3 pbv of a third particle having a D50 particle size of 0.7. The D50 (Vol. Average)=[(19.1×12.2)+(8.0×1.5)+(2.3×0.7)]/[19.1+8.0+2.3]. In this case, the D50 (Vol. Average)=8.4. For a thermal grease formulation having a single, thermally conductive particle type, the D50 (Vol. Average) is the value of D50 for the particular particle distribution. In TCG formulations which included fumed silica, the fumed silica was not included in the calculation of D50 (Vol. Average), as fumed silica was not considered to be a useful, thermally conductive particle.

### Screen Printability

Screen printability was accessed by screen printing the thermal grease through an 80 mesh screen, which corresponds to about 177 micron openings, onto a 2.5 cm×2.5 cm nylon sheet. The screen was also about 2.5 cm×2.5 cm. The nylon sheet was placed in a cavity of similar length and width having a depth of about 1.5 cm. The cavity was formed in a block of aluminum, 7 cm×4 cm×2 cm. The screen was placed on the nylon sheet. Thermal grease was placed on the screen near one edge. A plastic, polyurethane, scraper, having base dimensions of about 2 cm×4 cm was scraped across the length of the screen, by hand, to force the grease into and through the screen. The sidewalls of the cavity acted as a guide for the plastic scraper. After removing the screen from the nylon sheet, the quality of the printed grease on the nylon sheet was visually accessed.

### Mixing Procedure

The thermal greases according to the formulations in Tables 1 through 5 were mixed according to the following general procedure. The values in the tables are on a weight basis. The main liquid component, Hatcol 2938 or AP 100 was added first, followed by the dispersant, fumed silica, Irganox 1010 (if used). If ZnO powder was used, either alone or in combination with another powder, it was added to the previous mixture, prior to mixing. These components were then mixed together under a high shear mixer at 2,500 rpm for about 3 minutes. After mixing, any additional powder was added and mixed under high shear at 2,500 rpm for about 3 minutes.

MATERIALS

| Abbreviation or | |
|---|---|
| Trade Name | Description |
| Hatcol 2938 | A polyol ester lubricant based on trimethylolpropane, available under the |
| | trade designation “HATCOL 2938” from Hatcol Corporation, |
| | Fords, New Jersey. |
| AP 100 | A silicone oil, available under the trade designation “SILICONE OIL AP |
| | 100” from Sigma-Aldrich, St. Louis, Missouri. |
| Solsperse 16000 | A 100% active polymeric dispersant, available under the trade designation |
| | “SOLSPERSE 16000 HYPERDISPERSANT” from Lubrizol Corporation, |
| | Wickliffe, Ohio. |
| Marvel 1186 | An oil based dispersant, available under the trade designation MARVEL |
| | 1186 from Marvel Chemical Co. Ltd., Taipei Taiwan. MARVEL 1186 is a |
| | direct translation of the equivalent Chinese trade name ChiGA 1186. |
| M5 | A medium surface fumed silica, available under the trade designation |
| | “CAB-O-SIL M5” from Cabot Corporation, Boston, Massachusetts. |
| TS 610 | A low surface area fumed silica, available under the trade designation |
| | “CAB-O-SIL TS-610” from Cabot Corporation. |
| Irganox 1010 | Pentaerythritol Tetrakis(3-(3,5-di-tert-butyl-4-hydroxyphenyl)propionate), |
| | a sterically hindered phenolic antioxidant, available under the trade |
| | designation “IRGANOX 1010” from BASF Corporation, Florham Park, |
| | New Jersey. |
| Al-12.2/58 | A spherical aluminum powder having a particle size D50 = 12.2 μm and a |
| | D100 = 55~61 μm, available from Li-Yu Technology Company, |
| | Chung-Li city, TaoYuan County, Taiwan. |
| Al-8.2/19.3 | A spherical aluminum powder having a particle size D50 = 8.2 μm and a |
| | D100 = 19.3 μm, available from Li-Yu Technology Company. |
| Al-4.5/11.9 | A spherical aluminum powder having a particle size D50 = 4.5 μm and a |
| | D100 = 11.9 μm, available from Li-Yu Technology Company. |
| Al-4.0/100 | A spherical aluminum powder having a particle size D50 = 4.0 μm and a |
| | D100 = 100 μm, available from Li-Yu Technology Company |
| Al-3.6/16.7 | A spherical aluminum powder having a particle size D50 = 3.6 μm and a |
| | D100 = 16.7 μm, available from Li-Yu Technology Company. |
| Al-3.6/14.2 | A spherical aluminum powder having a particle size D50 = 3.6 μm and a |
| | D100 = 14.2 μm, available from Li-Yu Technology Company. |
| Al2O3-4.0/10.2 | An aluminum oxide powder having a particle size D50 = 4.0 μm and a |
| | D100 = 10.2 μm, available from Li-Yu Technology Company. |
| SiC-1.5/6.0 | A silicon carbide powder having a particle size D50 = 1.5 μm and a |
| | D100 = 6.0 μm, available from Chien Cheng Griding Chemical Co., Ltd. |
| | Ping-Jen city, TaoYuan County, Taiwan. |
| ZnO-0.9/3.2 | A zinc oxide powder having a particle size D50 = 0.90 μm and a |
| | D100 = 3.2 μm, available from Ta-Chuan Zinc Oxide Company, |
| | Yingge town, TaoYuan County, Taiwan. |
| ZnO-0.7/3.1 | A spherical ZnO powder having a particle size D50 = 0.73 μm and a |
| | D100 = 3.1 μm, available from Li-Yu Technology Company. |

Using the mixing procedure described above, thermal grease compositions were prepared according to the formulations described in Tables 1, 2, 3, 4 and 5. Examples are designated by “Ex.” and comparative examples are designated by “CE”. Using the thermal resistance test method, the thermal resistance for each sample was measured. Results are shown in Tables 1, 2, 3, 4 and 5. For some samples, the screen printability was also examined, per the above screen printability test method. Results are in Table 1 and 5.

TABLE 1

| Component | CE-1 | CE-2 | Ex. 1 | Ex. 2 | Ex. 3 |
|---|---|---|---|---|---|
| Hatcol 2938 | 6.3 | 19.97 | 19.97 | 15.09 | 13.9 |
| Solsperse 16000 | 3.6 | — | — | — | — |
| Marvel 1186 | — | 2.3 | 2.3 | 2.4 | 2.4 |
| Irganox 1010 | 0.1 | — | — | — | — |
| M5 | — | 0.99 | 0.99 | 0.99 | 1 |
| Al-12.2/58 | 51.56 | — | — | — | — |
| Al-4.5/11.9 | — | — | — | 9.05 | 73.4 |
| SiC-1.5/6.0 | 25.63 | — | — | | |
| ZnO-0.9/3.2 | — | — | 76.8 | 72.4 | 9.1 |
| ZnO-0.7/3.1 | 12.81 | 76.8 | — | | |
| D50 (Vol. Average) | 8.4 | 0.7 | 0.9 | 1.6 | 4.3 |
| Screen Printability | Poor | Poor | Excellent | Excellent | Excellent |
| Thermal Resistance | 0.130 | — | 0.194 | 0.117 | 0.103 |
| I_{cm}(° C. × cm²/W) | | | | | |

TABLE 2

| Component | CE-3 | Ex. 4 | Ex. 5 | Ex. 6 |
|---|---|---|---|---|
| Hatcol 2938 | 15 | 15 | 15 | 15 |
| Marvel 1186 | 2 | 2 | 2 | 2 |
| M5 | 2 | 2 | 2 | 2 |
| Al-12.2/58 | 81 | — | — | — |
| Al-8.2/19.3 | — | 81 | — | — |
| Al-4.5/11.9 | — | — | 81 | — |
| Al2O3-4.0/10.2 | — | — | | 81 |
| D50 (Vol. Average) | 12.2 | 8.2 | 4.5 | 4.0 |
| Thermal Resistance | 0.49 | 0.23 | 0.13 | 0.076 |
| I_{cm}(° C. × cm²/W) | | | | |

TABLE 3

| Component | Ex. 7 | Ex. 8 | Ex. 9 | Ex. 10 | Ex. 11 | Ex. 12 |
|---|---|---|---|---|---|---|
| Hatcol 2938 | 15 | 15 | 16 | 15 | 13.5 | 13.5 |
| Marvel 1186 | 2.4 | 2.4 | 2.4 | 4.7 | 4.5 | 4.5 |
| TS 610 | 1.8 | 1.8 | 1.77 | 1.6 | 1.35 | 1.35 |
| Al-12.2/58 | 59.9 | — | 39.8 | — | 21 | — |
| Al-8.2/19.3 | — | — | — | 39.5 | — | 21 |
| Al-4.5/11.9 | — | 59.9 | — | — | — | — |
| Al-3.6/14.2 | 21 | 21 | 39.5 | 39.5 | 59.9 | 59.9 |
| D50 (Vol. Average) | 10.0 | 4.3 | 7.9 | 5.9 | 5.8 | 4.8 |
| Thermal Resistance | 0.22 | 0.131 | 0.167 | 0.139 | 0.222 | 0.096 |
| I_{cm}(° C. × cm²/W) | | | | | | |

TABLE 4

| Component | Ex. 13 | Ex. 14 | Ex. 15 | Ex. 16 | Ex. 17 | Ex. 18 | Ex. 19 | Ex. 20 |
|---|---|---|---|---|---|---|---|---|
| Hatcol 2938 | 16 | 15 | 15 | 15 | 15 | 16 | 15 | — |
| AP 100 | — | — | — | — | — | — | — | 4.0 |
| Marvel 1186 | 4.7 | 2.4 | 2.4 | 4.7 | 2.4 | 2.4 | 2.4 | 0.8 |
| TS 610 | 1.8 | 1.8 | 1.8 | 1.8 | 1.6 | 1.6 | 1.8 | 0.3 |
| Al-12.2/58 | 57.6 | — | — | — | — | — | — | — |
| Al-8.2/19.3 | — | 59.9 | — | — | 71.9 | 74.9 | — | — |
| Al-4.5/11.9 | — | — | 59.9 | — | — | — | 71.9 | — |
| Al-3.6/14.2 | — | — | — | 58.5 | — | — | — | 20.0 |
| ZnO-0.9/3.2 | 20.2 | 21 | 21 | 20.5 | 9.0 | 6.0 | 9 | 2.0 |
| D50 (Vol. Average) | 10.6 | 7.1 | 4.0 | 3.2 | 7.8 | 7.9 | 4.3 | 3.5 |
| Thermal Resistance | 0.198 | 0.14 | 0.131 | 0.092 | 0.121 | 0.17 | 0.127 | .091 |
| I_{cm}(° C. × cm²/W) | | | | | | | | |

TABLE 5

| Component | Ex. 21 | Ex. 22 | Ex. 23 |
|---|---|---|---|
| Hatcol 2938 | 1.35 | 1.35 | 1.35 |
| Marvel 1186 | 0.4 | 0.4 | 0.4 |
| TS610 | 0.1 | 0.1 | 0.1 |
| Al-3.6/14.2 | — | — | 11 |
| Al-3.6/16.7 | — | 11 | — |
| Al-4.0/100 | 11 | — | — |
| ZnO-0.9/3.2 | 1 | 1 | 1 |
| D50 (Vol. Average) | 3.7 | 3.4 | 3.4 |
| Screen Printability | Excellent | Excellent | Excellent |
| Thermal Resistance | 0.094 | 0.0764 | 0.07 |
| I_{cm}(° C. × cm²/W) | | | |

As illustrated in the Tables, even if the same conductive particle loading, the size of the particles used in the TCG formulation affects the thermal resistance of the TCG. As the size of the particle decreases, the thermal resistance also decreases. For example, in Table 2, the TCG formulation of Example 6 had the smallest particle size, and had the lowest thermal resistance. Surprisingly, it has been found that the thermal resistance of the TCG exhibits a minimum value when the D50 (Vol. Average) particle size is no greater than about 5 microns and no less than about 2 microns.

Tables 1-4 show that even with the addition of other conductive particles into the TCG formulation, the maximum size of the particles has the greatest effect on the thermal resistance of the TCG. In addition, the data in Table 4 shows that when the particle size of the thermally conductive particles are the same, an increase in the particle loading decreases the thermal resistance.

Although the present invention has been described with reference to preferred embodiments, workers skilled in the art will recognize that changes may be made in form and detail without departing from the spirit and scope of the invention.

1. A thermally conductive grease comprising:
a carrier oil;
a dispersant; and
thermally conductive particles, wherein the thermally conductive particles have a D50 (Vol. Average) particle size of no greater than about 11 microns, and wherein the thermally conductive particles in the thermally conductive grease contain less than about 3% by volume of particles having a particle size of 0.7 microns or less, based on a total volume of thermally conductive particles in the thermally conductive grease.

2. The thermally conductive grease of claim 1, wherein the carrier oil is one of a hydrocarbon based carrier oil and a silicone oil.

3. The thermally conductive grease of claim 1, wherein when the carrier oil is a hydrocarbon based carrier oil, the carrier oil is selected from the group consisting of: polyol esters, epoxides, and polyolefins or a combination thereof.

4. The thermally conductive grease of claim 1, further comprising a thixotropic agent.

5. The thermally conductive grease of claim 1, wherein the thermally conductive particles comprise materials selected from the group consisting of: diamond, polycrystalline diamond, silicon carbide, alumina, boron nitride (hexagonal or cubic), boron carbide, silica, graphite, amorphous carbon, aluminum nitride, aluminum, zinc oxide, nickel, tungsten, silver, and combinations thereof.

6. The thermally conductive grease of claim 1, wherein the thermally conductive particles have a D50 (Vol. Average) particle size of no greater than about 7 microns.

7. The thermally conductive grease of claim 1, wherein the thermally conductive particles have a D50 (Vol. Average) particle size of no greater than about 5 microns.

8. The thermally conductive grease of claim 1, wherein the thermally conductive particles have a D50 (Vol. Average) particle size of no less than about 0.9 microns.

9. A microelectronic package comprising:
a substrate;
at least one microelectronic heat source attached to the substrate; and
the thermally conductive grease of claim 1 on the at least one microelectronic heat source.

10. The microelectronic package of claim 9, further comprising a heat spreader, wherein the thermally conductive grease is present between the microelectronic heat source and the heat spreader.

11. The microelectronic package of claim 10, further comprising a heat dissipation device, wherein the thermally conductive grease is present between the heat spreader and the heat dissipation device.

12. A method of making a thermally conductive grease comprising:
providing carrier oil, dispersant, and thermally conductive particles, wherein the thermally conductive particles have a D50 (Vol. Average) particle size of no greater than about 11 microns, and wherein the thermally conductive particles in the thermally conductive grease contain less than about 3% by volume of particles having a particle size of 0.7 microns or less, based on a total volume of thermally conductive particles in the thermally conductive grease;
mixing the carrier oil and dispersant to form a mixture; and
mixing the thermally conductive particles into the mixture.

13. The method of claim 12, wherein the thermally conductive particles have a D50 (Vol. Average) particle size of no greater than about 7 microns.

14. The method of claim 12, wherein the thermally conductive particles have a D50 (Vol. Average) particle size of no greater than about 5 microns.

15. A thermally conductive grease comprising:
a carrier oil;
a dispersant; and
thermally conductive particles, wherein the thermally conductive particles have a D50 (Vol. Average) particle size of less than about 7 microns and greater than about 0.9 microns.

16. The thermally conductive grease of claim 15, wherein the thermally conductive particles have a D50 (Vol. Average) particle size of less than about 5 microns and greater than about 2 microns.
